(19) United States
(12) Patent Application Publication
(10) Pub. No.: US 2011/0199138 A1
(43) Pub. Date: Aug. 18, 2011

(54) Semiconductor device and test method thereof

(75) Inventor: Yutaka Sano, Kawagawa (JP)

(73) Assignee: Renesas Electronics Corporation, Kawasaki (JP)

(21) Appl. No.: 12/929,755

(22) Filed: Feb. 14, 2011

(30) Foreign Application Priority Data
Feb. 16, 2010 (JP) 2010-031194

(51) Int. Cl. H03L 7/06

(52) U.S. Cl. 327/158; 327/159

(57) ABSTRACT

A semiconductor device includes a PLL (Phase Locked Loop) circuit configured to generate a reception clock signal and a transmission clock signal based on a reference clock signal which has been subjected to frequency-modulation; a serializer configured to convert parallel data into serial data in response to the transmission clock signal to output the serial data; and a CDR (Clock Data Recovery) circuit configured to perform clock data recovery on reception data in response to the reception clock signal to output recovery data. A deserializer is configured to convert the recovery data into parallel data; and a loop-back line configured to supply the serial data outputted from the serializer to the CDR circuit as the reception data.

### INCORPORATION BY REFERENCE

This patent application claims a priority on convention based on Japanese Patent Application No. 2010-31194 filed on Feb. 16, 2010. The disclosure thereof is incorporated herein by reference.

### TECHNICAL FIELD

The present invention relates to a semiconductor device and a test method therefor, and in particular to a semiconductor device including a high-speed serial interface circuit and a loop-back test method thereof.

### BACKGROUND ART

Recently, the operation speed of an input/output serial interface circuit of a semiconductor integrated circuit as exemplified by PCI-Express has been increased to allow transmission and reception of a signal in GHz band. The serial interface circuit is generally provided with a transmitter (a transmission section), a receiver (a receipt section), and a PLL (phase locked loop) circuit that generates a transmission clock signal and a reception clock signal based on a reference frequency signal (a reference clock signal). In addition, the receiver is provided with a clock data recovery circuit (a CDR circuit).

The CDR circuit adjusts a phase of the reception clock signal generated by the PLL circuit, and generates a clock signal suitable to sample reception data (hereinafter referred to as a recovery clock signal). Thus, even if a phase of the reception data is changed, the reception data can be received correctly because the clock signal is recovered by following the change. This function is referred to as a phase-following function.

An LSI tester is required for such a test of the high-speed serial interface circuit to output or sample a GHz-class signal. However, the LSI tester having such a function is very expensive, so that a test cost increases.

Then, in order to reduce the test cost, a loop-back test is generally employed by which transmission data from the transmitter is fed back as it is to its own receiver.

FIG. 1 shows a configuration of a serial interface circuit according to a conventional technique. Here, the serial interface circuit shown in http://focus.ti.com/lit/ds/symlink/tlk2501.pdf will be described (Non Patent Literature 1).

The serial interface circuit shown in FIG. 1 is provided with a PLL circuit 51, a serializer 53, a CDR circuit 55, and a deserializer 57. The PLL circuit 51 generates the transmission clock signal 52 and a reception clock signal 54 based on a reference clock signal 50. The serializer 53 is provided in the transmitter, to convert parallel data into serial data in synchronization to the transmission clock signal. The CDR circuit 55 and the deserializer 57 are provided in the receiver. The CDR circuit 55 recovers a clock signal as a recovery clock signal 56 from the received serial data bases on the reception clock signal. The deserializer 57 converts the received serial data into parallel data in synchronization with the recovery clock signal 56.

Here, when the loop-back test is carried out, selectors 58 and 59 on a receiver side are controlled by a LOOPEN signal, thereby connecting the transmitter (TX) to the receiver (RX) by a loop-back line 60. Thus, the serial data supplied from the transmitter (serializer 53) is received by the receiver (the deserializer 57). In the loop-back test, the parallel data transmitted from an internal circuit is compared with the parallel data acquired from the serial data that is received via the loop-back line 60, thereby carrying out the verification of the function of the serial interface circuit.

However, since the PLL circuit 55 recovers the transmission clock signal 52 and the reception clock signal 54 based on the single reference clock signal 50, the frequency of the transmission clock signal 52 is coincident with that of the reception clock signal 54. Thus, the frequency of the serial data received through the loop-back line 60 by the receiver (RX) is coincident with that of the recovery clock signal 56 recovered by the CDR circuit 55.

Accordingly, since no change occurs at all in the phase difference between the recovery clock signal 56 and the reception data after a suitable clock signal is recovered by the CDR circuit 55 at the initial stage of reception, the phase-following function is disabled. Therefore, since the phase-following function of the CDR circuit is not activated in the conventional loop-back test, the loop-back test cannot be carried out in a communication state similar to the actual operation.

As described above, in the loop-back test of the serial interface circuit that controls the transmission/reception based on a common reference clock signal, the phase of the reception data becomes always constant after a predetermined time elapsed. Thus, the phase-following function of the CDR circuit is rarely activated after the clock signal is recovered in the initial stage of reception. Therefore, no defect can be detected even if there is any defect in this function, which results in degradation in test quality.

On the other hand, JP 2005-257376A (Patent Literature 1) and JP 2008-219754A (Patent Literature 2) disclose loop-back test methods in which verification of the phase-following function of the CDR circuit can be performed even if the transmission clock signal and the reception clock signal are recovered in response to the single reference clock signal.

In Patent Literature 1, a mechanism for forcibly changing the phase of the reception clock signal is provided in a CDR circuit, so that a phase difference is generated between the recovery clock signal and the reception data (the reception clock signal). On the other hand, in Patent Literature 2, pseudo random data corresponding to the reference clock signal is outputted to a transmitter-side PLL circuit, so that the transmission clock signal containing random jitter is recovered, thereby the frequency difference is generated between the transmission clock signal and the reception clock signal. As described above, since a phase difference is generated between the recovery clock signal and the reception clock signal even if the transmission clock signal and the reception clock signal are recovered in response to a single reference clock signal, it is possible to verify the phase-following function of the CDR circuit. This improves a rate of defect detection in the serial interface circuit.

### CITATION LIST

[Patent Literature 1]: JP 2005-257376A

[Patent Literature 2]: JP 2008-219754A

[Non Patent Literature 1]: TLK 2501 1.5 TO 2.5 GBPS TRANSCEIVER, P4 FIG. 1, [online], 2003, TEXAS INSTRUMENTS, Internet http://focus.ti.com/lit/ds/symlink/tlk2501.pdf

### SUMMARY OF THE INVENTION

The CDR circuit disclosed in Patent Literature 1 performs different operations in a loop-back test operation and in a normal operation. Thus, even if a defect of the CDR circuit is detected through the loop-back test operation, it cannot be specified whether the cause is in the phase-following function of the CDR circuit or the function for forcibly changing the phase of the reception clock signal. Accordingly, in the test method disclosed in Patent Literature 1, the CDR circuit in which no defect is detected in the normal operation may be detected as a defective CDR circuit.

In Patent Literature 2, since it is required to provide the transmitter-side PLL circuit for recovering the transmission clock signal containing a random jitter separately from the receiver-side PLL circuit, the number of elements and the circuit area increase. Furthermore, the transmitter-side PLL circuit in the loop-back test operation recovers the transmission clock signal through an operation different from that in the normal operation. Thus, when a defect of the CDR circuit is detected in the loop-back test, it cannot be specified whether the cause is in the phase-following function of the CDR circuit or in the function of recovering the transmission clock signal. Accordingly, in the test method disclosed in Patent Literature 2, the CDR circuit in which no defect is detected in the normal operation may be detected as a defective CDR circuit.

In an aspect of the present invention, a semiconductor device includes: a PLL (Phase Locked Loop) circuit configured to generate a reception clock signal and a transmission clock signal based on a reference clock signal which has been subjected to frequency-modulation; a serializer configured to convert parallel data into serial data in response to the transmission clock signal to output the serial data; a CDR (Clock Data Recovery) circuit configured to perform clock data recovery on reception data in response to the reception clock signal to output recovery data; a deserializer configured to convert the recovery data into parallel data; and a loop-back line configured to supply the serial data outputted from the serializer to the CDR circuit as the reception data.

In another aspect of the present invention, a test method is achieved by generating a reception clock signal and a transmission clock signal by a PLL (Phase Locked Loop) circuit based on a reference clock signal which has been subjected to frequency-modulation; by serializing parallel data into serial data by a serializer in response to the transmission clock signal; by supplying the serial data as reception data from the serializer to a CDR (Clock Data Recovery) circuit through a loop-back line; by performing clock data recovery on the reception data in response to the reception clock signal by the CDR circuit to generate recovery data; and by converting the recovery data into parallel data by a deserializer.

Therefore, according to the present invention, the phase-following function of the CDR circuit in the serial interface circuit can be test through the loop-back test. Furthermore, the phase-following function of the CDR circuit in the serial interface circuit can be subjected to the loop-back test in a same state as the actual operation. Moreover, the test quality of the loop-back test to the serial interface circuit can be improved.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a diagram showing a configuration of a serial interface circuit according to a conventional technique;

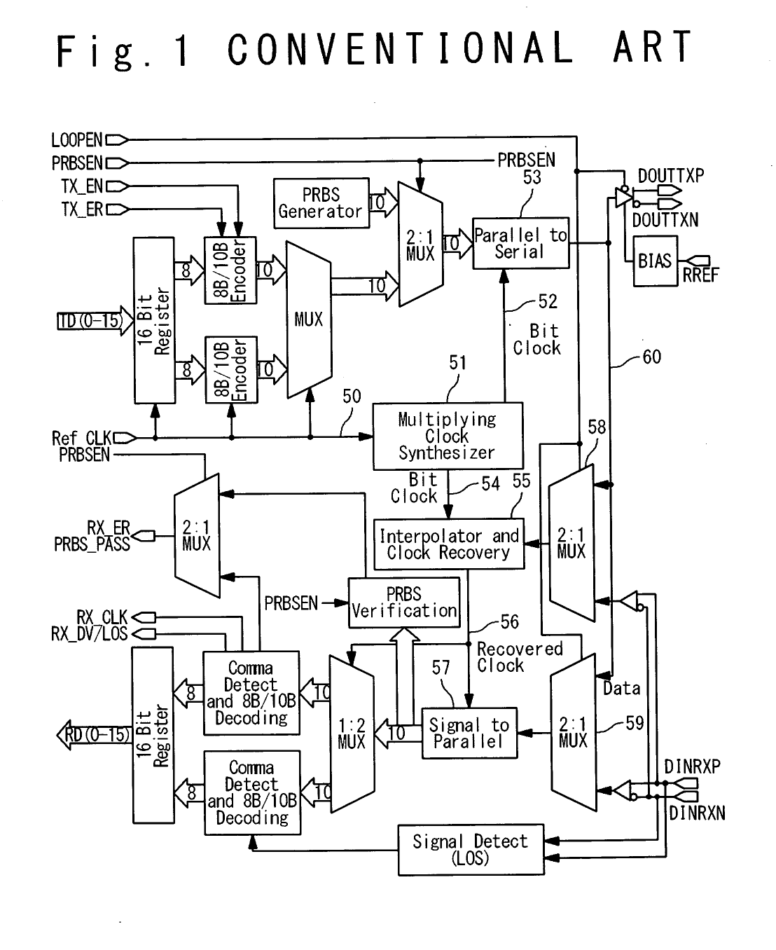

FIG. 2 is a diagram showing a configuration of a semiconductor device including a serial interface circuit according to a first embodiment of the present invention;

FIG. 3 is a diagram showing an example of a frequency difference between a recovery clock signal and reception data in a loop-back test of the present invention;

FIG. 4 is a diagram showing another example of a frequency difference between the recovery clock signal and the reception data in the loop-back test of the present invention;

FIG. 5 is a diagram showing a relation of a change of a frequency difference between the recovery clock signal and the reception data, and a frequency of adjustment of the frequency difference in the loop-back test of the present invention;

FIG. 6 is a diagram showing an example of a configuration of the serial interface circuit according to a second embodiment of the present invention;

FIG. 7 is a diagram showing another example of a configuration of the serial interface circuit according to the second embodiment of the present invention; and

FIG. 8 is a diagram showing still another example of a configuration of the serial interface circuit according to the second embodiment of the present invention.

### DESCRIPTION OF EMBODIMENTS

Hereinafter, a semiconductor device including a serial interface circuit according to the present invention will be described below in detail with reference to the attached drawings.

### First Embodiment

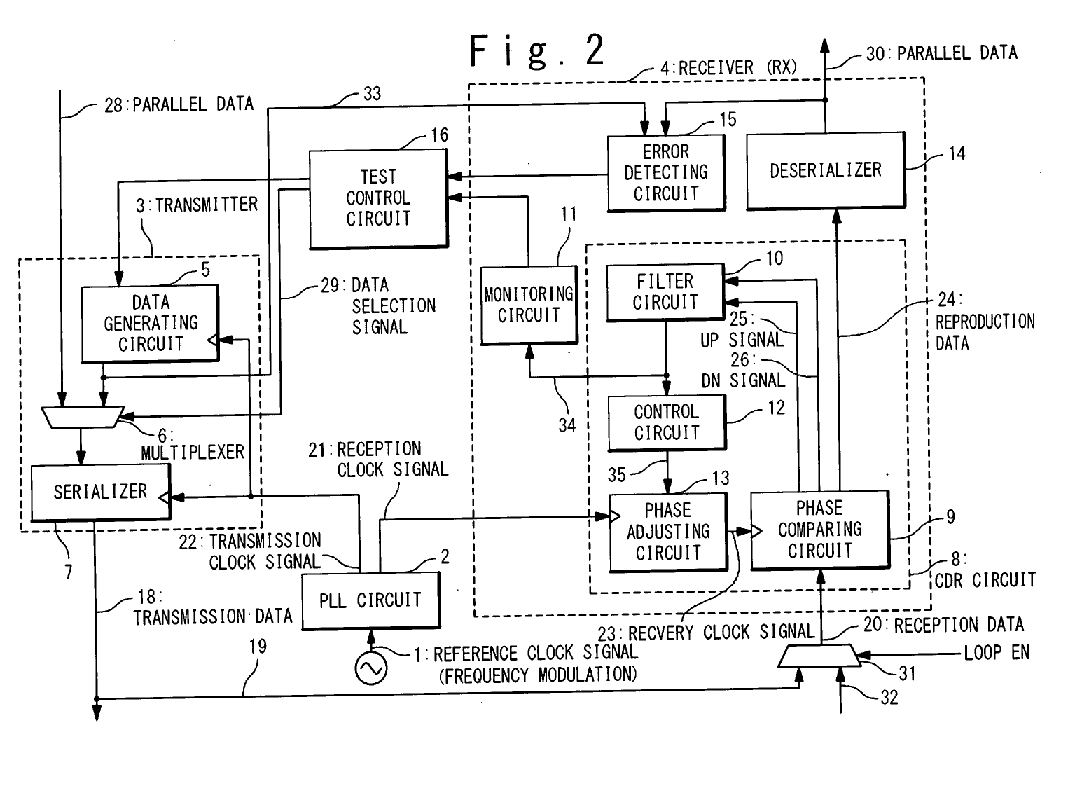

Referring to FIGS. 2 to 5, the serial interface circuit according to a first embodiment of the present invention will be described. A configuration of a GHz-class high-speed serial interface circuit in a test mode will be described below.

### (Configuration)

Initially, a configuration of the serial interface in the first embodiment will be described with reference to FIG. 2. FIG. 2 shows the configuration of the serial interface circuit according to the first embodiment of the present invention. The serial interface circuit of the first embodiment is provided with a PLL circuit 2, a transmitter (a transmission section) 3, a receiver (a reception section) 4, a test control circuit 16, a loop-back line 19, and a selector 31.

The PLL circuit 2 generates a reception clock signal 21 and a transmission clock signal 22, both of which have a same frequency, in response to a single reference clock signal 1. Here, in a normal operation of the serial interface circuit, an external clock signal 1 of a given frequency is supplied as a reference clock signal 1 to the PLL circuit 2. On the other hand, in a loop-back test operation, the reference clock signal 1 generated through the frequency-modulation of a modulation degree to the external clock signal with a signal of a predetermined frequency is supplied to the PLL circuit 2. For example, a spread-spectrum clock signal generated by SSCG (Spread Spectrum Clock Generator) is supplied as the reference clock signal 1 to the PLL circuit 2.

Here, a modulation frequency and the modulation degree of the reference clock signal 1 are preferably variable. However, the modulation frequency of the reference clock signal 1 is set to be lower than a cut-off frequency of a loop filter (not shown) mounted on the PLL circuit 2. Thus, the modulation frequency of the reference clock signal 1 is transferred as it is to the reception clock signal 21 and the transmission clock signal 22 that are generated by the PLL circuit 2.

Furthermore, an increase in the modulation degree of the reference clock signal 1 causes a large variation in a signal interval, resulting in a high delay effect. Thus, there is a larger difference between the frequency of transmission data 18 which is received as a reception data 20 through a loop back and that of a recovery clock signal 23. Therefore, it is possible to change verification quality of the phase-following ability of a CDR circuit by changing the modulation degree of the reference clock signal.

A loop-back line 19 is not used in the normal operation, but is used in the loop-back test operation as a signal line that connects an output of the transmitter 3 and an input of the receiver 4. The selector 31 selects one of serial data 32 received from an external signal line and the serial transmission data 18 received from the loop-back line 19 in response to a control signal LOOP EN. The selector 31 selects the serial data 32 received from the external signal line in the normal operation, and the transmission data 18 received through the loop-back line 19 in the loop-back test operation. The selected data is outputted as the reception data 20 to the receiver 4.

The transmitter 3 is provided with a data generating circuit 5, a multiplexer 6, and a serializer 7. The data generating circuit 5 generates parallel data 33 having a predetermined pattern (hereinafter, to be referred to as test data 33) in response to an instruction signal from the test control circuit 16. The test data 33 is supplied to the multiplexer 6 and an error detecting circuit 15. The multiplexer 6 selects one of parallel data 28 outputted from an internal circuit (not shown) and the test data 33 in response to a data selection signal 29 from the test control circuit 16. The selected data is outputted to the serializer 7. The multiplexer 6 outputs the parallel data 28 from the internal circuit to the serializer 7 in the normal operation, and the test data 33 to the serializer 7 in the loop-back test operation. The serializer 7 converts the parallel data outputted from the multiplexer 6 into the transmission data 18, which is serial data, in synchronization with the transmission clock signal 22. The transmission data 18 is outputted and supplied to the selector 31 through the loop-back line 19.

The receiver 4 is provided with a clock signal data recovering circuit (CDR circuit) 8, a monitoring circuit 11, an error detecting circuit 15, and a deserializer 14.

The CDR circuit 8 adjusts the phase of the reception clock signal 21 to generate a recovery clock signal 23, and extracts (samples) recovery data 24 from the reception data 20 in synchronization with the recovery clock signal 23. The deserializer 14 converts the recovery data 24 extracted in the CDR circuit 8 into parallel data 30, and the parallel data 30 is supplied to the internal circuit (not shown) and the error detecting circuit 15. The monitoring circuit 11 monitors a comparison result 34 as a difference between the frequency of the reception data 20 and that of the recovery clock signal 23 in the CDR circuit 8, and the comparison result 34 is notified to the test control circuit 16. The error detecting circuit 15 determines whether the parallel data 30 and the test data 33 are coincident with each other, and the determination result is notified to the test control circuit 16 as an error determination result (e.g., a bit error rate value).

Next, a detailed configuration of the CDR circuit 8 will be described. The CDR circuit 8 is provided with a phase comparing circuit 9, a filter circuit 10, a control circuit 12, and a phase adjusting circuit 13.

The phase comparing circuit 9 extracts the recovery data 24 from the reception data 20 in synchronization with the recovery clock signal 23 generated by the phase adjusting circuit 13, and the recovery data 24 is outputted to the deserializer 14. The phase comparing circuit 9 compares the phase of the recovery clock signal 23 with that of the reception data 20 in a predetermined period, and a signal is outputted to indicate the phase comparison result (an up (UP) signal 25/a down (DN) signal 26). Specifically, the phase comparing circuit 9 outputs the UP signal 25 when the phase of the recovery clock signal 23 delays in comparison with that of the reception data 20, and outputs the a DN signal when the phase of the recovery clock signal 23 leads in comparison with that of the received data.

The filter circuit (an averaging circuit) 10 averages phase comparison result signals (the UP signal 25 and the DN signal 26) for a predetermined time period. For example, the filter circuit 10 has a counter that counts up in response to the UP signal 25 and counts down in response to the DN signal 26. In this case, the filter circuit 10 outputs the count value for every time period as an averaged phase comparison result signal (the comparison result 34) to the control circuit 12. The control circuit 12 generates a phase control signal 35 for shifting and changing the phase of the reception clock signal 21 based on the comparison result 34. The phase adjusting circuit 13 shifts the phase of the reception clock signal 21 in response to the phase control signal 35, to generate the recovery clock signal 23. For example, the phase adjusting circuit 13 is controlled to lead the phase of the reception clock signal 21 when the value of the comparison result 34 is higher than “0”, and to delay the phase of the reception clock signal 21 when the value of the comparison result 34 is lower than “0”. In addition, when the comparison result 34 is “0”, the reception clock signal 21 is outputted as the recovery clock signal 23 without shifting the phase thereof.

As described above, a negative feedback loop from the phase comparing circuit 9 to the phase adjusting circuit 13 adjusts the phase of the recovery clock signal 23 to be optimum for reception of the reception data 20.

Here, the monitoring circuit 11 monitors the comparison result 34 generated by the filter circuit 10 in the loop-back test operation for each time period, and determines if frequencies of generation of the UP signal 25 and the DN signal 26 are within a predetermined range. A monitoring resultant signal is outputted to the test control circuit 16.

The test control circuit 16 outputs an instruction signal to the data generating circuit 5 and a data selection signal 29 to the multiplexer 6 thereby carrying out a sequence control of the transmitter 3 in the loop-back test operation. Furthermore, the test control circuit 16 receives an error detection signal from the error detecting circuit 15 and the monitoring resultant signal from the monitoring circuit 11 to determine the test result. For example, a bit error rate indicated by the error detection signal and a signal indicative of a preset threshold value are compared with each other. If the bit error rate indicated by the error detection signal exceeds the threshold value, it is determined that the transmitter 3 or the receiver 4 is defective. Otherwise, the test control circuit 16 receives the monitoring resultant signal outputted from the monitoring circuit 11, acquires the frequency of generation of the defective state in which the difference between the frequency of the recovery clock signal 23 and that of the reception data 20 exceeds a predetermined range, and compares the frequency of the generation with a reference value (a phase-followable range set to the CDR circuit 8). At this time, if the frequency of generation of the defective state is equal to or higher than the reference value, the test control circuit 16 determines that any defect is present in the phase following function of the CDR circuit 8.

### (Operation)

Next, an operation of a loop-back test to the serial interface according to the present invention will be described in detail with reference to FIGS. 2 to 5. When a mode is set to a loop-back test mode, the loop-back line 19 connects the transmitter 3 to the receiver 4. Furthermore, the test data 33 is transmitted from the transmitter 3 to the receiver 4.

A cut-off frequency of a loop filter (not shown) in the PLL circuit 2 is higher than the modulation frequency of the reference clock signal 1. Therefore, the modulation frequency of the reference clock signal 1 is also transferred as it is to the reception clock signal 21 and the transmission clock signal 22 generated by the PLL circuit 2. Specifically, the frequency of the reception data 20 (a reception data frequency 100) and the frequency of the recovery clock signal 23 (a recovery clock signal frequency 200) vary in a same period. On the other hand, the transmission data 18 is delayed due to a parasitic capacitance of a path through the loop-back line 19 from the transmitter 3 to the receiver 4. Specifically, one of the reception clock signal 21 and the transmission clock signal 22 is delayed. As a result, a frequency difference 300 (a phase difference) is generated between the reception data 20 and the recovery clock signal 23.

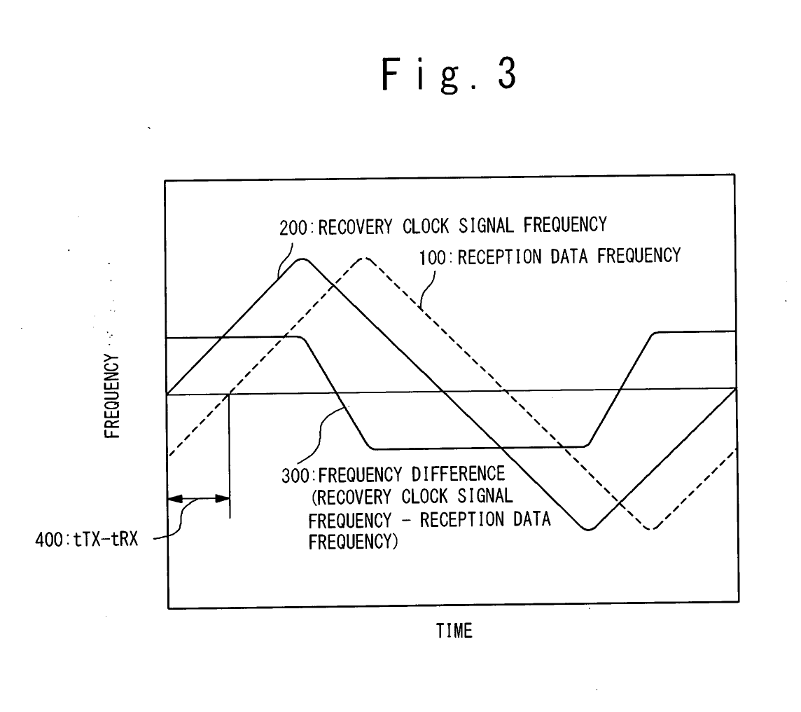

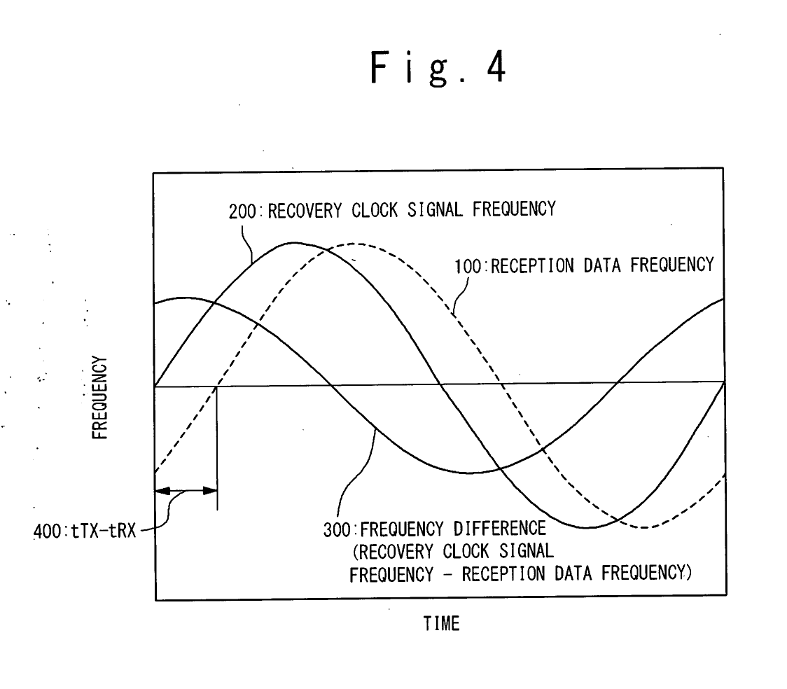

The frequency difference (the phase difference) generated between the reception data 20 and the recovery clock signal 23 will be described in detail with reference to FIGS. 3 and 4.

Here, tRX is a delay time necessary for the modulation frequency of the reference clock signal 1 to be transferred from the PLL circuit 2 to the reception clock signal 21, and to pass through the phase adjusting circuit 13 to the phase comparing circuit 9. Likewise, tTX is a delay time necessary for the modulation frequency of the reference clock signal 1 to be transferred from the PLL circuit 2 to the transmission clock signal 22, and for the serial data (the transmission data 18) transmitted based on the transmission clock signal 22 to pass through the loop-back line 19 to reach the phase comparing circuit 9. In these cases, the frequency difference 300 between the reception data 20 and the recovery clock signal 23 in the phase comparing circuit 9 is generated based on a delay difference 400 of “tTX-tRX”.

FIG. 3 shows an example of the frequency difference 300 between the reception data 20 and the recovery clock signal 23 when the modulation frequency of the reference clock signal 1 varies in a triangle waveform. Furthermore, FIG. 4 shows an example of the frequency difference 300 between the reception data 20 and the recovery clock signal 23 when the modulation frequency of the reference clock signal 1 changes in a sine waveform.

The frequencies of the recovery clock signal 23 and the reception data 20 change with time as shown in FIGS. 3 and 4. In this case, the reception data frequency 100 changes with the delay difference 400 “tTX-tRX” in comparison with the recovery clock signal 23. Therefore, the frequency difference 300 between the recovery clock signal 23 and the reception data 20, i.e. (the recovery clock signal frequency 200—the reception data frequency 100) changes in the same period as the modulation frequency, as shown in FIGS. 3 and 4.

As described above, since the frequency difference 300 (the phase difference) between the reception data 20 and the recovery clock signal 23 changes with time, the phase-following function of the CDR circuit 8 is kept activated.

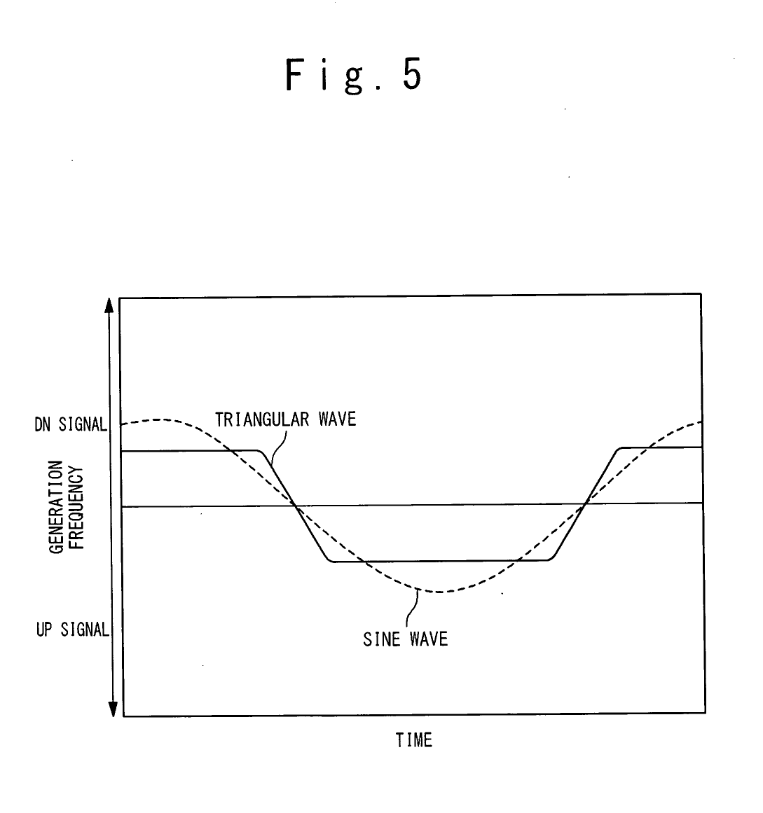

At this time, the phase comparing circuit 9 generates the UP signal 25 and the DN signal 26 based on the frequency difference 300. For example, the UP signal 25 is outputted when the frequency difference 300 (the recovery clock signal frequency 200—the reception data frequency 100) is negative, whereas the DN signal 26 is outputted when the frequency difference 300 is positive. The frequency of generation of the UP signal 25 and the DN signal 26 changes in proportion to the absolute value of the frequency difference 300. For example, the frequency of generation of the UP signal 25 and the DN signal 26 based on the frequency difference 300 shown in FIGS. 3 and 4 changes as shown in FIG. 5. Specifically, the frequency of the adjustment to the reception clock signal 21 changes based on to the frequency difference 300.

The monitoring circuit 11 determines at a certain time interval the frequency of the generation of the UP signal 25 and the DN signal 26, i.e., the frequency of the adjustment to the reception clock signal 21 changing periodically as well as with in a predetermined range. At the same time, by detecting no error in the reception data 20, the error detecting circuit 15 can test whether the phase-following function of the CDR circuit 8 properly operates in a communication state almost similar to the actual operation.

Here, the frequency difference 300 can be controlled by changing the modulation frequency and/or modulation degree of the reference clock signal 1. In addition, a suitable test condition can be set by changing the modulation frequency and/or modulation degree of the reference clock signal 1.

When the serial interface circuit is used, there is a case that a frequency offset is present to a reference frequency source (a reference clock signal source) of a transmission counter end, or a spread-spectrum clock signal generator (SSCG) is used in order to reduce electromagnetic interference (EMI) of the transmission data. In such a case, the phase of the reception data 20 always changes. According to the present invention, such a phase change can be reproduced by the frequency modulation and delay to the transmitted/reception data, so that the serial interface circuit can be tested under the communication environment similar to the actual state.

Also, according to the present invention, the data transfer operation in the PLL circuit 2, the transmitter 3 and the CDR circuit 8 in the loop-back test operation is same as that of the normal operation. Therefore, according to the present invention, it is possible to avoid detecting the product having no defect in the normal operation as a defective product, thereby improving a detection rate of defect of the serial interface circuit.

Moreover, when the serial interface circuit has an SSCG (not shown), the loop-back test using the SSCG is carried out, separately from the above-mentioned test without using it, and a defect of the SSCG can be detected.

### Second Embodiment

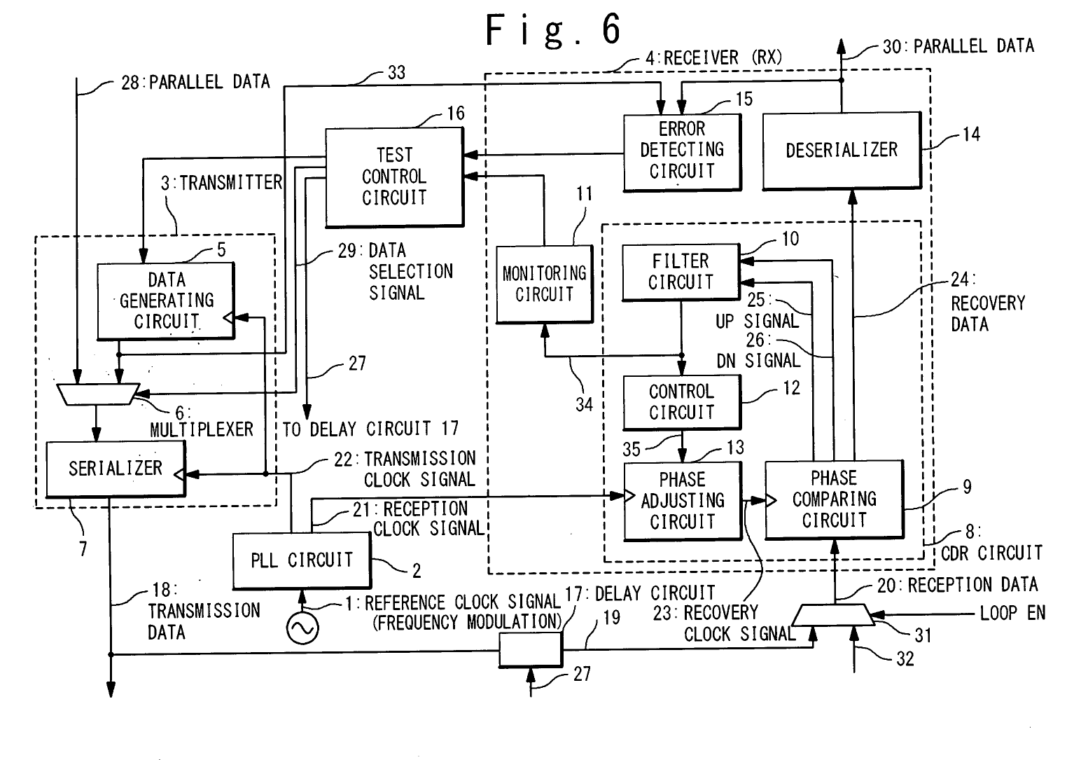

Referring to FIGS. 6 to 8, the serial interface circuit according to a second embodiment of the present invention will be described. In the first embodiment, the delay difference 400 that generates the frequency difference 300 mainly depends on an amount of delay due to the loop-back line 19. However, the frequency difference 300 may not be large sufficiently to activate the CDR circuit 8, depending on the magnitude of the delay difference 400. For example, when the amount of delay is equivalent to one period of the reception data frequency 100, no delay difference 400 exists to the recovery clock signal frequency 200. Thus, it is preferable to further provide a delay circuit 17 for generating or changing the delay difference 400, in addition to the serial interface circuit in the first embodiment.

FIG. 6 shows a configuration of the serial interface circuit according to the second embodiment of the present invention. Referring to FIG. 6, the serial interface circuit in the second embodiment is provided with the delay circuit 17 for delaying the transmission data 18 on the loop-back line 19. The delay circuit 17 also preferably changes a delay time in response to a delay control signal 27 from the test control circuit 16. The other components are same as those of the first embodiment.

The test control circuit 16 controls the delay circuit 17 only in the loop-back test operation to delay the transmission data 18 on the loop-back line 19. In addition, the amount of delay of the delay circuit 17 is preferably adjustable within a predetermined range.

In the present embodiment, since the delay circuit 17 can change the delay time “tTX” necessary for the modulation frequency transferred by the transmission clock signal 22 to pass through the loop-back line 19 to the phase comparing circuit 9, the frequency difference 300 between the reception data 20 and the recovery clock signal 23 can be set optionally. Thus, the condition of the phase-following function verification to the CDR circuit 8 can be changed flexibly.

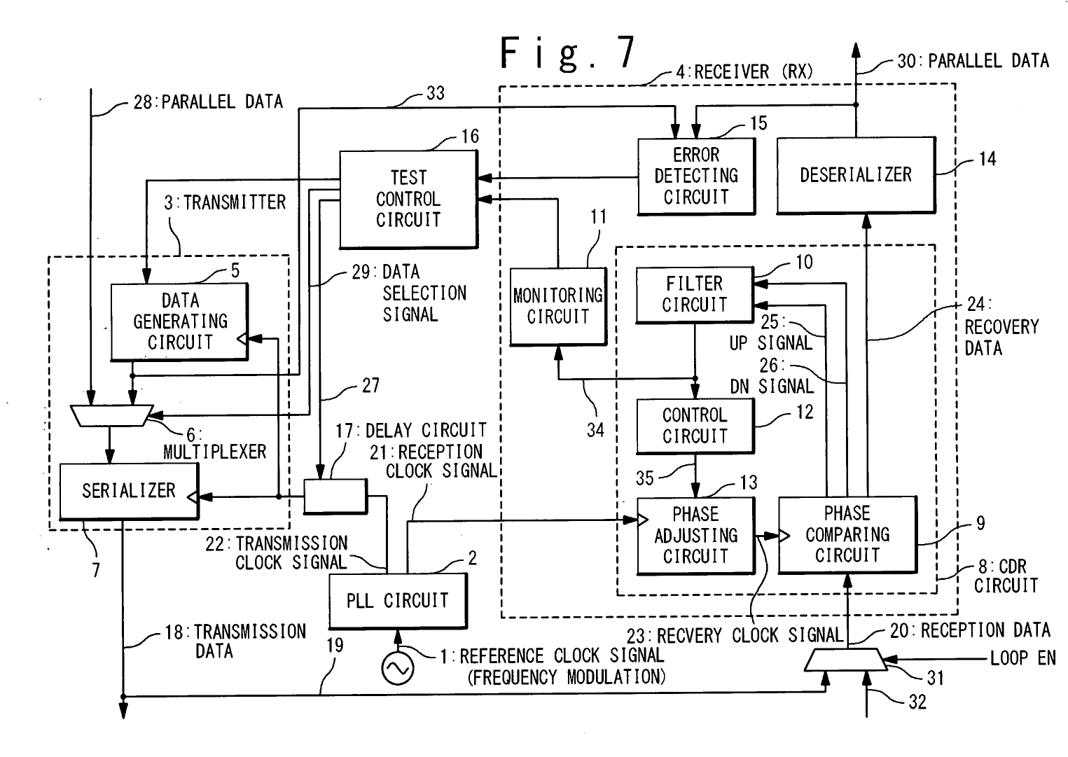

The delay circuit 17 may be arranged not only on the loop-back line 19, but between the PLL circuit 2 and the transmitter 3 (the serializer 7) as shown in FIG. 7. In this case, the delay circuit 17 delays the transmission clock signal 22 by a predetermined delay amount in response to the delay control signal 27.

In an example shown in FIG. 7, since the delay circuit 17 can change the delay time “tTX”, the frequency difference 300 between the reception data 20 and the recovery clock signal 23 can be set optionally, similar to the above. In addition, the delay circuit 17 is preferably controlled so as to pass the transmission clock signal 22 with a minimum delay time in the normal operation, and apply a desired delay only in the loop-back test operation.

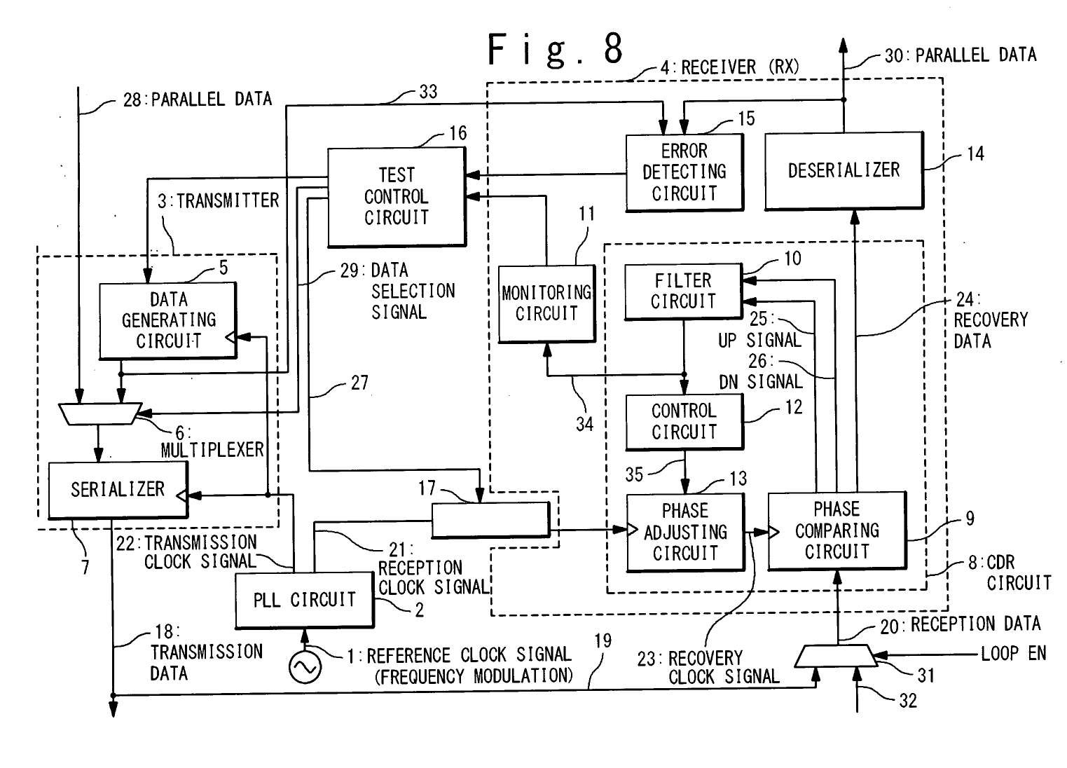

Likewise, the delay circuit 17 may be arranged between the PLL circuit 2 and the receiver 4 (the phase adjusting circuit 13) as shown in FIG. 8. In this case, the delay circuit 17 delays the reception clock signal 21 by a predetermined delay amount in response to the delay control signal 27.

In an example shown in FIG. 8, since the delay circuit 17 can change the delay time “tRX” necessary for the modulation frequency transferred by the reception clock signal 21 to pass through the phase adjusting circuit 13 to the phase comparing circuit 9, the frequency difference 300 between the reception data 20 and the recovery clock signal 23 can be set arbitrarily. In addition, the delay circuit 17 is preferably controlled so as to pass the reception clock signal 21 with a minimum delay time in the normal operation, and apply a desired delay only in the loop-back test operation.

However, in the example shown in FIG. 8, since the delay time “tRX” is larger than the delay time “tTX”, the relation between the reception data frequency 100 and the recovery block frequency 200 is opposite to that in the first embodiment. The recovery clock signal frequency 200 is delayed in comparison with the reception data 20 by the delay difference 400 of “tRX-tTX”. Therefore, the frequency difference 300 is defined as (the reception data frequency 100—the recovery clock signal frequency 200). The other operations are the same as those of the first embodiment.

As described above, according to the present invention, one of the transmission data 18 and the recovery clock signal 23 to both of which the same modulation frequency is transferred is delayed, so that the frequency difference can be generated between the reception data 20 received through the loop-back line and the recovery clock signal 23. Thus, the loop-back test operation can be carried out while verifying the phase-following function of the CDR circuit 8 in a communication state almost similar to the actual operation.

Although the embodiments of the present invention have been described above in detail, the specific configuration in the present invention is not be limited to the embodiments described above, but modifications without departing from the scope of the invention are included. In addition, the embodiment described above can be combined within a range in which there is no technical contradiction. For example, the delay difference may be generated between the reception data 20 and the recovery clock signal 23, the delay circuit 17 may be provided in any one of or all of paths between the PLL circuit 2 and the serializer 7, between the PLL circuit 2 and the CDR circuit 8, and on the loop-back line 19.

What is claimed is:

1. A semiconductor device comprising:
a PLL (Phase Locked Loop) circuit configured to generate a reception clock signal and a transmission clock signal based on a reference clock signal which has been subjected to frequency-modulation;
a serializer configured to convert parallel data into serial data in response to said transmission clock signal to output the serial data;
a CDR (Clock Data Recovery) circuit configured to perform clock data recovery on reception data in response to said reception clock signal to output recovery data;
a deserializer configured to convert the recovery data into parallel data; and
a loop-back line configured to supply the serial data outputted from said serializer to said CDR circuit as the reception data.

2. The semiconductor device according to claim 1, wherein said CDR circuit comprises a phase adjusting circuit configured to generate a recovery clock signal used to extract the recovery data from the reception data by adjusting a phase of said reception clock signal, and
wherein said semiconductor device further comprises a delay circuit configured to generate a delay difference between said recovery clock signal and the reception data which is outputted to said CDR circuit through said loop-back line.

3. The semiconductor device according to claim 2, wherein said delay circuit is provided on said loop-back line to delay a signal which passes through said loop-back line.

4. The semiconductor device according to claim 2, wherein said delay circuit is provided between said PLL circuit and said serializer to delay said transmission clock signal.

5. The semiconductor device according to claim 2, wherein said delay circuit is provided between said PLL circuit and said CDR circuit to delay said reception clock signal.

6. The semiconductor device according to claim 2, further comprising: a test control circuit configured to set a delay time of said delay circuit.

7. The semiconductor device according to claim 1, further comprising:
a data generating circuit configured to generate test parallel data; and
an error detecting circuit configured to perform an error determination based on a comparison result of the test parallel data and the parallel data outputted from said deserializer.

8. The semiconductor device according to claim 1, further comprising:
a monitoring circuit configured to monitor whether or not a frequency of adjustment of the reception clock signal in said CDR circuit is within a predetermined range.

9. The semiconductor device according to claim 8, further comprising:
a test control circuit configured to determine whether or not there is a defect in a phase-following function of said CDR circuit, based on the monitoring result of said monitoring circuit.

10. The semiconductor device according to claim 1, wherein said reference clock signal is modulated with a frequency which is lower than a cut-off frequency of a loop filter in said PLL circuit.

11. The semiconductor device according to claim 1, further comprising:
a selector configured to select one of an external signal line and said loop-back line in response to a control signal so as to connect with said CDR circuit.

12. A test method comprising:
generating a reception clock signal and a transmission clock signal by a PLL (Phase Locked Loop) circuit based on a reference clock signal which has been subjected to frequency-modulation;
serializing parallel data into serial data by a serializer in response to said transmission clock signal;
supplying the serial data as reception data from said serializer to a CDR (Clock Data Recovery) circuit through a loop-back line;
performing clock data recovery on the reception data in response to said reception clock signal by said CDR circuit to generate recovery data; and
converting the recovery data into parallel data by a deserializer.

13. The test method according to claim 12, wherein said performing comprises:
generating a recovery clock signal used to extract said recovery data from said reception data by adjusting a phase of said reception clock signal by said CDR circuit,
wherein said test method further comprises:
generating a delay difference between said recovery clock signal and the reception data supplied to said CDR circuit through said loop-back line by a delay circuit.

14. The test method according to claim 13, wherein said generating a delay difference comprises:
delaying a signal which passes through said loop-back line.

15. The test method according to claim 13, wherein said generating a delay difference comprises:
delaying said transmission clock signal.

16. The test method according to claim 13, wherein said generating a delay difference comprises:
delaying said reception clock signal.

17. The test method according to claim 13, further comprising:
setting a delay time generated by said delay circuit.

18. The test method according to claim 12, further comprising:
generating test parallel data; and
executing an error determination based on a comparing result of the test parallel data and the parallel data outputted from said deserializer.

19. The test method according to any of claim 12, further comprising:
monitoring whether or not a frequency of adjustment of the reception clock signal by said CDR circuit is within a predetermined range.

20. The test method according to claim 19, further comprising:
determining whether or not there is a defect in a phase-following function of said CDR circuit, based on said monitoring result.
